(19) United States
(12) Patent Application Publication
(10) Pub. No.: US 2025/0392212 A1
(43) Pub. Date: Dec. 25, 2025

(54) SWITCHING POWER SUPPLY

(71) Applicant: Murata Manufacturing Co., Ltd., Kyoto-fu (JP)

(72) Inventors: Tatsuya HOSOTANI, Nagaokakyo-shi (JP); Hiroyuki TAKATSUJI, Nagaokakyo-shi (JP)

(73) Assignee: Murata Manufacturing Co., Ltd., Kyoto-fu (JP)

(21) Appl. No.: 19/311,059

(22) Filed: Aug. 27, 2025

Related U.S. Application Data
(63) Continuation of application No. PCT/JP2024/002401, filed on Jan. 26, 2024.

(30) Foreign Application Priority Data
Mar. 13, 2023 (JP) 2023-038590

(51) Int. Cl. H02M 3/155; H05K 1/18

(52) U.S. Cl. CPC H02M 3/155; H05K 1/181; H05K 2201/10015; H05K 2201/1003; H05K 2201/10166

(57) ABSTRACT

A circuit board includes first and second wiring patterns and a reference-potential-side wiring pattern. The first wiring pattern electrically connects a node between first and second switching elements, and a first terminal to each other. The second wiring pattern electrically connects a second terminal and an output capacitor to each other. In plan view of the circuit board, the first wiring pattern has an area smaller than an area of the second wiring pattern. The inductor has a parasitic capacitor between the first and second terminals due to the construction of a winding conductor and a magnetic core. Due to the positioning of the circuit board with respect to a chassis, at the switching frequency of the first and second switching elements, the parasitic capacitor of the inductor is greater in capacitance than a parasitic capacitor between the magnetic core and the chassis.

### CROSS-REFERENCE TO RELATED APPLICATIONS

This application claims benefit of priority to International Patent Application No. PCT/JP2024/002401, filed Jan. 26, 2024, and to Japanese Patent Application No. 2023-038590, filed Mar. 13, 2023, the entire contents of each are incorporated herein by reference.

### BACKGROUND

### Technical Field

The present disclosure relates to a switching power supply including a switching element for power conversion.

### Background Art

Japanese Unexamined Patent Application Publication No. 2018-98853 describes a DC-DC converter. The DC-DC converter described in Japanese Unexamined Patent Application Publication No. 2018-98853 includes a switching element, and an inductor connected to the output side of the switching element. The DC-DC converter in Japanese Unexamined Patent Application Publication No. 2018-98853 also includes a shield member.

The switching element, the inductor, and the shield member are mounted on a substrate. The shield member is disposed on the substrate so as to surround the inductor.

### SUMMARY

The presence of the shield member not related to power conversion, however, leads to an unwanted increase in the size of the DC-DC converter (switching power supply). In the case of the configuration described in Japanese Unexamined Patent Application Publication No. 2018-98853, providing no shield member would result in switching noise being radiated from the inductor to the external environment.

Accordingly, the present disclosure provides a high-efficiency and compact switching power supply with reduced radiation of switching noise.

A switching power supply according to the present disclosure includes an input capacitor, a first switching element, a second switching element, an inductor, an output capacitor, and a circuit board. The first switching element and the second switching element are electrically connected to the input capacitor. The inductor includes a winding conductor, a magnetic core, a first terminal electrically connected to one end of the winding conductors, and a second terminal electrically connected to an other end of the winding conductor. The input capacitor, the first switching element, the second switching element, the inductor, and the output capacitor are mounted to the circuit board.

The circuit board includes a first wiring pattern, a second wiring pattern, and a reference potential pattern. The first wiring pattern electrically connects a connection node between the first switching element and the second switching element, and the first terminal to each other. The second wiring pattern electrically connects the second terminal and the output capacitor to each other. In plan view of the circuit board, the first wiring pattern has an area smaller than an area of the second wiring pattern. The inductor has, between the first terminal and the second terminal, an internal parasitic capacitance of the inductor due to construction of the winding conductor and the magnetic core. Due to positioning of the circuit board with respect to a chassis, at a switching frequency at which the first switching element and the second switching element are operated, the internal parasitic capacitance of the inductor is greater than an external parasitic capacitance between the magnetic core and the chassis. The internal parasitic capacitance of the inductor, the second wiring pattern, the output capacitor, the reference potential pattern of the circuit board, the input capacitor, and the first wiring pattern constitute a noise-balancing circuit formed by a closed electric circuit.

The noise-balancing circuit cancels generation of electromagnetic noise caused by the switching operation of the first switching element and the second switching element, and reduces generation of common-mode noise caused by switching noise radiated or conducted from the inductor.

The present disclosure can provide a high-efficiency and compact switching power supply that includes a noise-balancing circuit formed without use of a noise reduction component, and that is configured to cancel generation of electromagnetic noise caused by switching operation, and to reduce switching noise radiation or conduction and common-mode noise caused by switching noise conduction.

### BRIEF DESCRIPTION OF THE DRAWINGS

FIG. 1 is a circuit diagram illustrating a schematic configuration of a switching power supply according to a first embodiment of the present disclosure;

FIG. 2 is an equivalent circuit diagram of an inductor according to the first embodiment of the present disclosure;

FIG. 3A is a plan view of the inductor according to the first embodiment of the present disclosure, and FIG. 3B is a side view of the inductor;

FIG. 4A is a see-through plan view of the inductor according to the first embodiment of the present disclosure, illustrating the configuration of its winding conductors, FIG. 4B is a see-through side view of the inductor illustrating the configuration of the winding conductors, and FIG. 4C and FIG. 4D are each a see-through plan view of the corresponding one of the winding conductors;

FIG. 5A is a side cross-sectional view of the switching power supply according to the first embodiment of the present disclosure, illustrating its configuration including a mounting portion where the inductor is mounted, and FIG. 5B is a plan view of the mounting portion;

FIG. 6 schematically illustrates the flow of EMI noise in the switching power supply according to the first embodiment of the present disclosure;

FIG. 7 schematically illustrates the flow of EMI noise in a switching power supply according to a comparative configuration;

FIG. 8A is a graph illustrating levels of conducted noise according to the present configuration and the comparative configuration, and FIG. 8B is a graph illustrating levels of radiated noise according to the present configuration and the comparative configuration;

FIG. 9 is a side cross-sectional view of a switching power supply according to a second embodiment of the present disclosure, illustrating its configuration including a mounting portion where the inductor is mounted;

FIG. 10 is a side cross-sectional view of a switching power supply according to a third embodiment of the present disclosure, illustrating its configuration including a mounting portion where the inductor is mounted;

FIG. 11 is a side cross-sectional view of a switching power supply according to a fourth embodiment of the present disclosure, illustrating its configuration including a mounting portion where the inductor is mounted;

FIG. 12 is a see-through side view of an inductor according to a fifth embodiment of the present disclosure, illustrating the configuration of its winding conductors;

FIG. 13 is a see-through side view of an inductor according to a sixth embodiment of the present disclosure, illustrating the configuration of its winding conductors;

FIG. 14A and FIG. 14B are see-through plan views of an inductor according to a seventh embodiment of the present disclosure, each illustrating the corresponding one of its winding conductors;

FIG. 15 is a see-through side view of an inductor according to an eighth embodiment of the present disclosure, illustrating the configuration of its winding conductors;

FIG. 16A is a side view of an inductor according to a ninth embodiment of the present disclosure illustrating its configuration, and FIG. 16B conceptually illustrates the inductor with conductor patterns wound around a magnetic core; and

FIG. 17 is a circuit diagram illustrating a schematic configuration of a switching power supply according to a tenth embodiment of the present disclosure.

### DETAILED DESCRIPTION

### First Embodiment

A switching power supply according to a first embodiment of the present disclosure will now be described with reference to the drawings.

### (Configuration of Switching Power Supply 10)

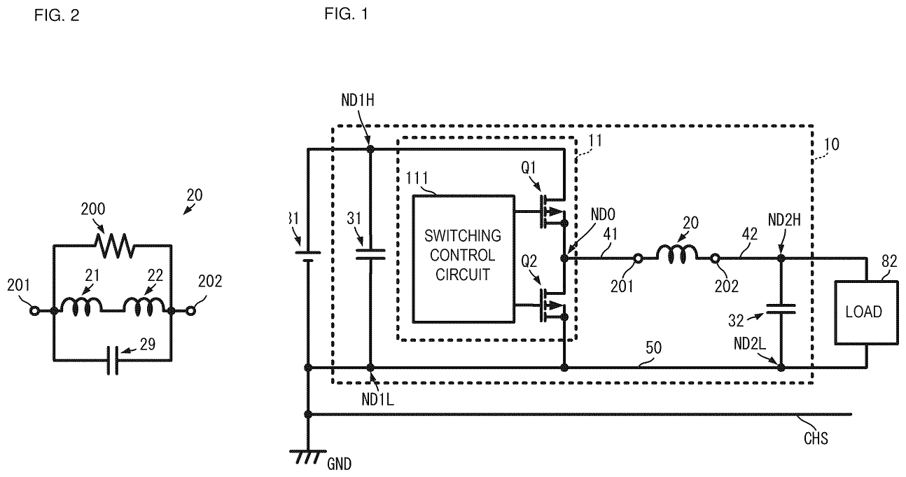

FIG. 1 is a circuit diagram illustrating a schematic configuration of the switching power supply according to the first embodiment of the present disclosure.

As illustrated in FIG. 1, a switching power supply 10 includes a switching IC 11, an inductor 20, an input capacitor 31, and an output capacitor 32. The switching IC 11 includes a switching control circuit 111, a switching element Q1, and a switching element Q2. The switching element Q1 corresponds to a “first switching element”, and the switching element Q2 corresponds to a “second switching element.” The switching element Q1 and the switching element Q2 are each a power semiconductor element, and implemented by, for example, an N-type MOS-FET.

The switching power supply 10 is electrically connected to a direct-current power source 81. More specifically, the input capacitor 31 is electrically connected in parallel with the direct-current power source 81. The connection point between the positive electrode of the direct-current power source 81 and the input capacitor 31 is a node ND1H, and the connection point between the negative electrode of the direct-current power source 81 and the input capacitor 31 is a node ND1L.

The switching element Q1 and the switching element Q2 are electrically connected in series with each other. More specifically, the source of the switching element Q1, and the drain of the switching element Q2 are electrically connected to each other. The connection point between the switching element Q1 and the switching element Q2 is a node ND0.

The switching element Q1 and the switching element Q2 are electrically connected to the input capacitor 31. More specifically, the drain of the switching element Q1 is connected to the node ND1H at the high side of the input capacitor 31. The source of the switching element Q2 is connected to the node ND1L at the low side of the input capacitor 31.

The switching control circuit 111 is electrically connected to the gate of the switching element Q1 and the gate of the switching element Q2. The switching element Q1 and the switching element Q2 switch the electrical conduction between the drain and the source on or off in response to a switching control signal provided from the switching control circuit 111.

The inductor 20 includes a first terminal 201, and a second terminal 202. Descriptions of specific electrical and physical configurations of the inductor 20, and specific wiring patterns connected to the inductor 20 will be given later, and are omitted here.

The first terminal 201 of the inductor 20 is connected to the node ND0 of the switching IC 11 via a wiring pattern 41. One terminal (high-side terminal) of the output capacitor 32 is connected the second terminal 202 of the inductor 20 via a wiring pattern 42. The connection point between the second terminal 202 of the inductor 20, and the one terminal of the output capacitor 32 is a node ND2H.

The other terminal (low-side terminal) of the output capacitor 32 is connected to a reference-potential-side wiring pattern 50. The connection point between the other terminal of the output capacitor 32 and the reference-potential-side wiring pattern 50 is a node ND2L.

The reference-potential-side wiring pattern 50 is connected to the node ND1L (the connection point between the negative electrode of the direct-current power source 81 and the input capacitor 31). The reference-potential-side wiring pattern 50 corresponds to a “reference potential pattern.”

The configuration mentioned above allows the switching power supply 10 to be implemented as a non-isolated step-down DC-DC converter (power conversion circuit).

A load 82 is electrically connected in parallel with the output capacitor 32. More specifically, one terminal of the load 82 is connected to the node ND2H, and the other terminal of the load 82 is connected to the node ND2L.

Further, the node ND1L (the connection point between the negative electrode of the direct-current power source 81 and the input capacitor 31) of the switching power supply 10 is electrically connected to a chassis CHS of, for example, a vehicle in which the switching power supply 10, the direct-current power source 81, and the load 82 are incorporated. The chassis CHS is connected to a ground potential as appropriate.

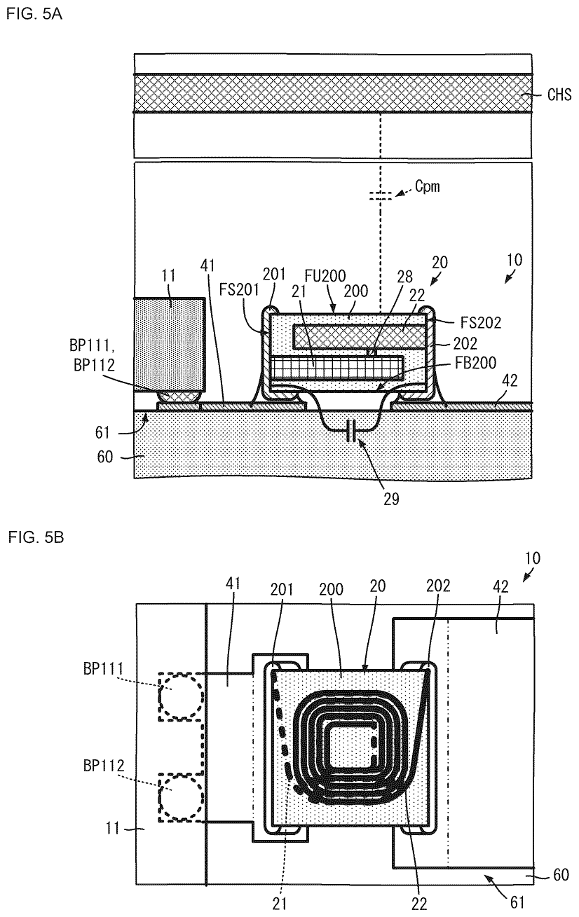

Specifically, the switching IC 11, the inductor 20, the input capacitor 31, and the output capacitor 32 are each implemented by a mountable electronic component. Wiring patterns for implementing the above-mentioned circuit configuration of the switching power supply 10 are provided at a circuit board 60 (see FIG. 5B and other figures described later). The switching power supply 10 is implemented by mounting of the switching IC 11, the inductor 20, the input capacitor 31, and the output capacitor 32 to the circuit board 60. The resulting circuit board 60 is physically and electrically connected to the chassis CHS.

### (Specific Configuration of Inductor 20, and Specific Configuration of Wiring Patterns Connected to Inductor 20)

### (Equivalent Circuit of Inductor 20)

FIG. 2 is an equivalent circuit diagram of the inductor according to the first embodiment of the present disclosure. The inductor 20 includes a first winding 21, a second winding 22, a magnetic core 200, the first terminal 201, and the second terminal 202. The first winding 21 and the second winding 22 are connected in series between the first terminal 201 and the second terminal 202.

The inductor 20 has a parasitic capacitor 29 connected between the first terminal 201 and the second terminal 202. In other words, the inductor 20 has the parasitic capacitor 29 connected in parallel with a series circuit of the first winding 21 and the second winding 22. The parasitic capacitor 29 has a capacitance determined by the construction of the first winding 21, the second winding 22, and the magnetic core 200. The parasitic capacitor 29 corresponds to an “internal parasitic capacitance of the inductor.”

Further, the inductor 20 has, between the first terminal 201 and the second terminal 202, a resistive component due to the magnetic core 200.

### (Specific Structure of Inductor 20)

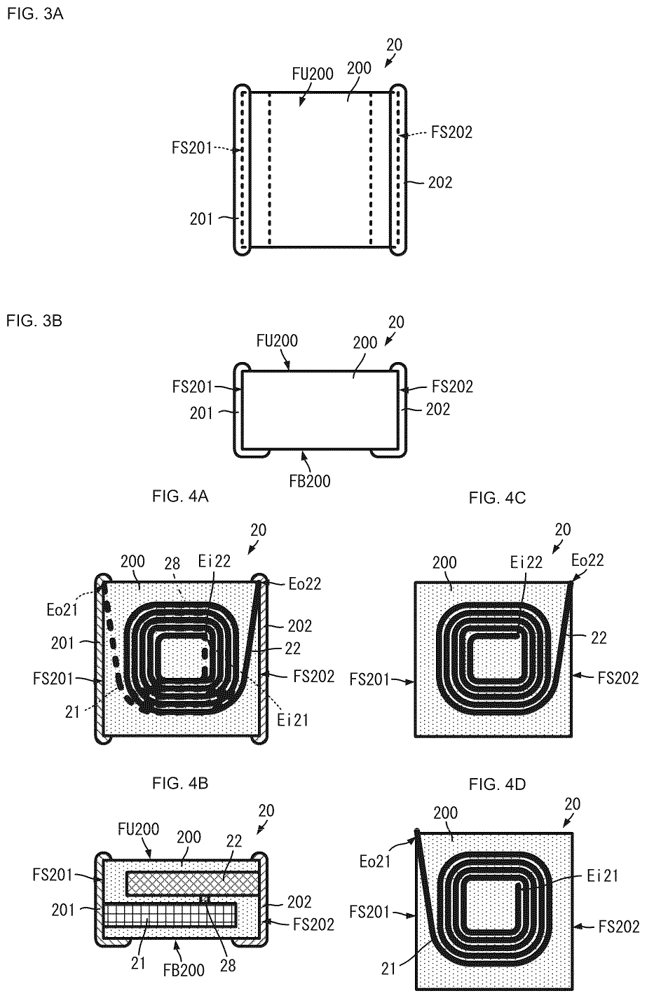

FIG. 3A is a plan view of the inductor according to the first embodiment of the present disclosure, and FIG. 3B is a side view of the inductor. FIG. 4A is a see-through plan view of the inductor according to the first embodiment of the present disclosure, illustrating the configuration of its winding conductors, FIG. 4B is a see-through side view of the inductor illustrating the configuration of the winding conductors, and FIG. 4C and FIG. 4D are each a see-through plan view of the corresponding one of the winding conductors.

As illustrated in FIG. 3A, FIG. 3B, FIG. 4A, and FIG. 4B, structurally, the inductor 20 includes the first winding 21, the second winding 22, the magnetic core 200, the first terminal 201, and the second terminal 202.

The magnetic core 200 is substantially cuboid in shape, and includes a top face FU200, a bottom face FB200, a side face FS201, a side face FS202, and the other two side faces. The side face FS201 and the side face FS202 are opposite to each other. The other two side faces are opposite to each other, and orthogonal and connected to the side face FS201 and the side face FS202. The side face FS201 corresponds to a “first side face”, and the side face FS202 corresponds to a “second side face.”

The first winding 21 and the second winding 22 are winding conductors formed by winding a flat conductor.

The first winding 21 has a coiled shape in plan view, and has a predetermined height. The height of the first winding 21 is greater than the thickness of the first winding 21, and the thickness of the flat conductor in plan view. The coiled shape of the first winding 21 includes an inner end portion Ei21, and an outer end portion Eo21.

The second winding 22 is similar in configuration to the first winding 21. The coiled shape of the second winding 22 includes an inner end portion Ei22, and an outer end portion Eo22.

The first winding 21 and the second winding 22 are contained in the magnetic core 200 so as to have a coiled shape in plan view. That is, the magnetic core 200 surrounds the first winding 21 and the second winding 22, and also fills the central opening of the coiled shape of each of the first winding 21 and the second winding 22.

The first winding 21 and the second winding 22 are stacked in the direction of height of the magnetic core 200. In this case, the first winding 21 is disposed closer to the bottom face FB200 than is the second winding 22. In other words, the first winding 21 and the second winding 22 are stacked in this order from the bottom face FB200 of the magnetic core 200 toward the top face FU200.

Due to the configuration mentioned above, the first winding 21 and the second winding 22 capacitively couple to each other to form the parasitic capacitor 29 (an internal parasitic capacitance of the inductor 20). The configuration mentioned above also results in formation of a resistive component due to the magnetic core 200.

The inner end portion Ei21 of the first winding 21, and the inner end portion Ei22 of the second winding 22 are connected by a connection conductor 28. The outer end portion Eo21 of the first winding 21 is exposed on the side face FS201 of the magnetic core 200. The outer end portion Eo22 of the second winding 22 is exposed on the side face FS202 of the magnetic core 200.

The first terminal 201 made of an electric conductor is provided so as to extend from the side face FS201 of the magnetic core 200 to the bottom face FB200. The outer end portion Eo21 of the first winding 21 is thus electrically connected to the first terminal 201.

The second terminal 202 made of an electric conductor is provided so as to extend from the side face FS202 of the magnetic core 200 to the bottom face FB200. The outer end portion Eo22 of the second winding 22 is thus electrically connected to the second terminal 202.

The configuration described above is employed to implement the equivalent circuit of the inductor 20 illustrated in FIG. 2.

### (Configuration of Mounting Portion for Inductor 20)

FIG. 5A is a side cross-sectional view of the switching power supply according to the first embodiment of the present disclosure, illustrating its configuration including a mounting portion where the inductor is mounted, and FIG. 5B is a plan view of the mounting portion. FIG. 5A and FIG. 5B depict the first winding 21 and the second winding 22 inside the inductor 20 so as to reveal the internal wiring of the inductor 20. In FIG. 5A, a circuit symbol representing a parasitic capacitor is also drawn for ease of understanding.

The circuit board 60 includes an insulative substrate, and various conductor patterns provided at the insulative substrate. The circuit board 60 includes a surface 61. Generally, the switching IC 11, the inductor 20, the input capacitor 31, and the output capacitor 32 are mounted to the surface 61 of the circuit board 60. The various conductor patterns include the wiring pattern 41, the wiring pattern 42, and the reference-potential-side wiring pattern 50, and are provided at the circuit board 60 together with the switching IC 11, the inductor 20, the input capacitor 31, and the output capacitor 32 in such a way as to implement the circuit configuration of the switching power supply 10 illustrated in FIG. 1.

The circuit board 60 is physically fixed to the chassis CHS by means of a fixing structure (not illustrated). The ground potential of the circuit board 60 is electrically connected (grounded) to the chassis CHS by means of an electrical connection structure (not illustrated).

The specific structure of the mounting portion for the inductor 20 is as described below.

As illustrated in FIGS. 5A and 5B, the wiring pattern 41 and the wiring pattern 42, each of which is a conductor pattern, are provided on the surface 61 of the circuit board 60.

One end of the wiring pattern 41 is provided with a land to which the source terminal of the switching element Q1 of the switching IC 11 is mounted, and a land to which the drain terminal of the switching element Q2 of the switching IC 11 is mounted. The source terminal of the switching element Q1, and the drain terminal of the switching element Q2 are mounted to the corresponding lands via bumps BP111 and BP112, respectively. Accordingly, the one end of the wiring pattern 41 corresponds to the node ND0.

The other end of the wiring pattern 41 is provided with a first inductor-mounting land. The first terminal 201 of the inductor 20 is mounted to the first inductor-mounting land by solder or other means. The first terminal 201 of the inductor 20 is thus electrically and physically connected to the wiring pattern 41.

One end of the wiring pattern 42 is spaced from the other end of the wiring pattern 41 by a distance based on the planar shape of the inductor 20. The one end of the wiring pattern 42 is provided with a second inductor-mounting land. The second terminal 202 of the inductor 20 is mounted to the second inductor-mounting land by solder or other means. The second terminal 202 of the inductor 20 is thus electrically and physically connected to the wiring pattern 42.

Although not illustrated, the one terminal (high-side terminal) of the output capacitor 32, and the one terminal of the load 82 are each electrically and physically connected to a predetermined position on the wiring pattern 42.

The inductor 20 is mounted to the circuit board 60 in such a way that the magnetic core 200 and the chassis CHS are spaced at a large distance from each other. More specifically, if the magnetic core 200 and the chassis CHS are disposed with a spacing from each other, a parasitic capacitor Cpm is formed between the magnetic core 200 and the chassis CHS. The parasitic capacitor Cpm corresponds to an “external parasitic capacitance of the inductor.” The inductor 20 is mounted to the circuit board 60 at a position where, at the switching frequency of the switching element Q1 and the switching element Q2, an impedance Z29 due to the parasitic capacitor 29 (the internal parasitic capacitance of the inductor 20) is smaller than an impedance Zcpm due to the parasitic capacitor Cpm (the external parasitic capacitance of the inductor 20). That is, the inductor 20 is mounted to the circuit board 60 at a position where the relationship Z29<Zcpm holds. In this case, it is preferable that the relationship Z<<Zcpm holds, and furthermore, it is preferable that at the frequencies of various harmonics of the switching frequency, the relationship Z29<Zcpm holds, and that the relationship Z<<Zcpm holds.

The impedance Z29 due to the parasitic capacitor 29, and the impedance Zcpm due to the parasitic capacitor Cpm can be measured by a device or system capable of measuring the impedance of an electric circuit, such as an impedance analyzer or a network analyzer.

Due to the above-mentioned configuration, in the switching power supply 10, a closed electric circuit for confining switching noise (electromagnetic noise) described below is formed to thereby implement a noise-balancing circuit.

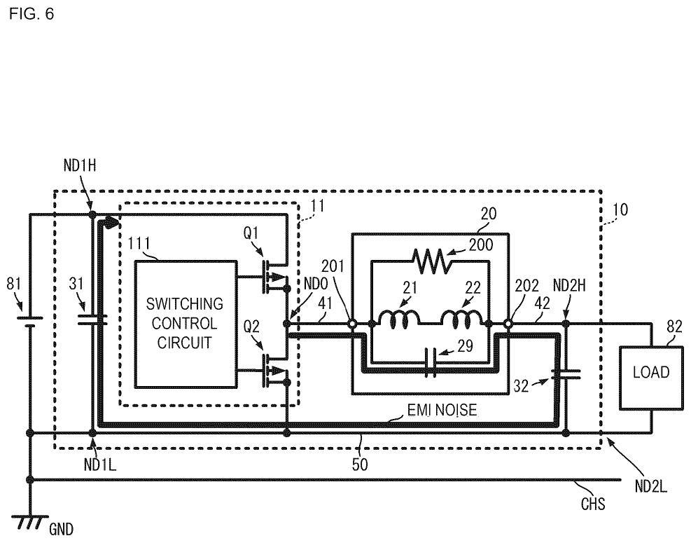

FIG. 6 schematically illustrates the flow of EMI noise in the switching power supply according to the first embodiment of the present disclosure.

As described above, the inductor 20 includes the parasitic capacitor 29, and the parasitic capacitor 29 is connected between the first terminal 201 and the second terminal 202. At the switching frequency of the switching element Q1 and the switching element Q2, the impedance Z29 due to the parasitic capacitor 29 (the internal parasitic capacitance of the inductor 20) is smaller than the impedance Zcpm due to the parasitic capacitor Cpm (the external parasitic capacitance of the inductor 20).

Accordingly, as indicated by thick arrows in FIG. 6, switching noise from the node ND0 of the switching IC 11 returns to the switching IC 11 via the wiring pattern 41, the parasitic capacitor 29 of the inductor 20, the wiring pattern 42, the output capacitor 32, the reference-potential-side wiring pattern 50, the input capacitor 31, and an input-side high-potential pattern. The input-side high-potential pattern refers to a wiring pattern that connects a high-side terminal of the input capacitor 31, and a high-side input terminal (a terminal connected to the drain terminal of the switching element Q1) of the switching IC 11 to each other.

The impedance due to the external parasitic capacitance of the inductor 20 is large relative to the switching noise. This reduces the propagation (leakage) of switching noise from the magnetic core 200 of the inductor 20 to the chassis CHS.

Due to the configuration described above, the switching power supply 10 includes a closed electric circuit for confining switching noise, which is implemented by the following components: the switching IC 11; the wiring pattern 41; the parasitic capacitor 29 of the inductor 20; the wiring pattern 42; the output capacitor 32; the reference-potential-side wiring pattern 50; the input capacitor 31; and the input-side high-potential pattern.

Switching noise generated from the switching IC 11 is confined within the closed electric circuit. Switching noise radiated from the first winding 21 is guided to the closed electric circuit by the second winding 22. Since continuously generated switching noise components are not constant in phase, such noise components cancel each other out when confined within the closed electric circuit. That is, the closed electric circuit functions as a noise-balancing circuit that balances switching noise components to thereby reduce generation of common-mode noise. In other words, the switching power supply 10 includes a noise-balancing circuit.

The above-mentioned configuration allows the switching power supply 10 to reduce generation and conduction of common-mode noise by reducing radiation or conduction of switching noise to the chassis CHS and to the external environment, and to reduce the level of switching noise by means of the noise-balancing circuit. That is, the above-mentioned configuration allows the switching power supply 10 to more effectively reduce radiation or conduction of switching noise, and generation and conduction of common-mode noise. The above-mentioned configuration also reduces superimposition of switching noise on the chassis CHS, and reduces generation of common-mode noise due to switching noise, and conduction of common-mode noise through the chassis CHS. This allows the switching power supply 10 to reduce the adverse influence that switching noise may have on various electronics of a vehicle equipped with the chassis CHS.

In this case, the switching power supply 10 does not additionally require another member (shield member) for reducing radiation or conduction of switching noise and for reducing generation and conduction of common-mode noise. This makes it possible to achieve simple configuration and miniaturization.

With a switching power supply 10P according to a comparative configuration that does not include the configuration of the switching power supply 10 according to the first embodiment, common-mode noise flows to the chassis CHS.

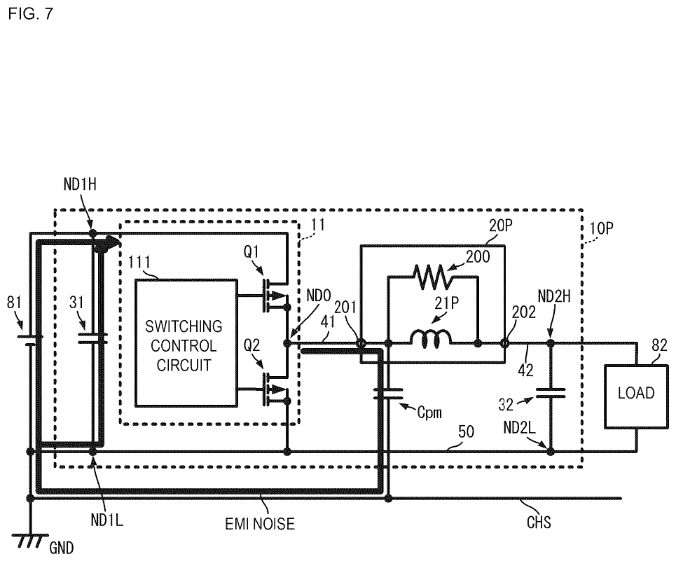

FIG. 7 schematically illustrates the flow of EMI noise in the switching power supply according to the comparative configuration. Unless the configuration and implementation of the inductor 20 as described above with reference to the switching power supply 10 according to the present disclosure are employed, then as illustrated in FIG. 7, the parasitic capacitor Cpm formed by the magnetic core 200 of the inductor 20 and the chassis CHS has a capacitance greater than the capacitance of the parasitic capacitor 29 of the inductor 20.

Consequently, with regard to the transmission of switching noise, the parasitic capacitor Cpm (the external parasitic capacitance of the inductor 20) becomes more dominant than the parasitic capacitor 29 (the internal parasitic capacitance of the inductor 20). This results in common-mode noise flowing to the chassis CHS through the parasitic capacitor Cpm.

As described above, with the switching power supply 10P according to the comparative configuration, common-mode noise leaks to the chassis CHS. Employing the above-mentioned configuration of the switching power supply 10 according to the first embodiment, however, makes it possible to reduce generation and conduction of common-mode noise caused by coupling of switching noise to the chassis CHS.

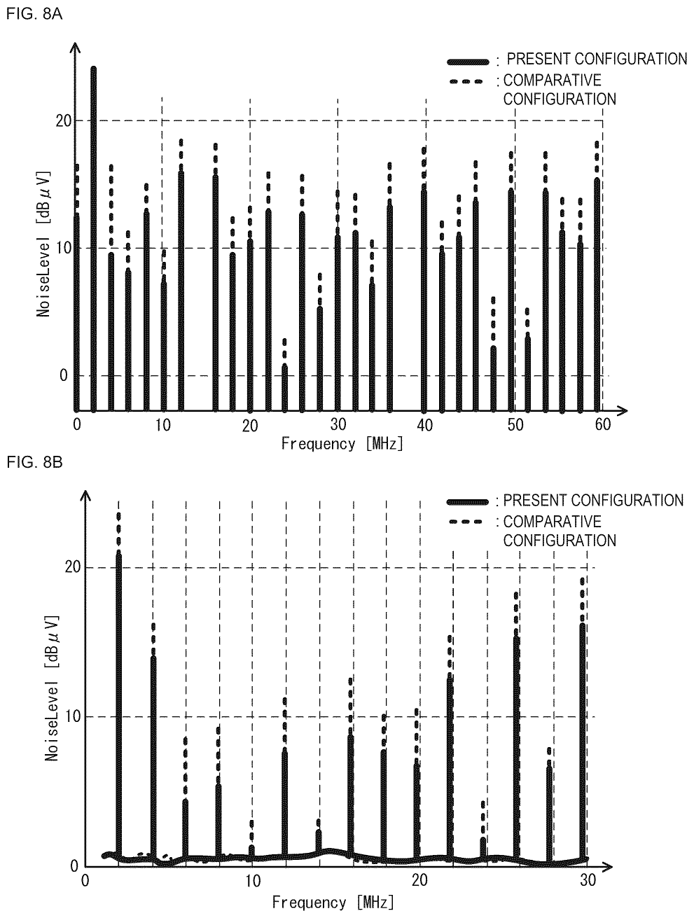

FIG. 8A is a graph illustrating levels of conducted noise according to the present configuration and the comparative configuration, and FIG. 8B is a graph illustrating levels of radiated noise according to the present configuration and the comparative configuration. Although FIG. 8A depicts only a partial frequency band, noise is distributed similarly for a wider frequency band. In FIG. 8A and FIG. 8B, solid lines represent the noise level according to the present disclosure, and dashed lines represent the noise level according to the comparative configuration. At locations where the noise level according to the present disclosure and the noise level according to the comparative configuration overlap, the noise level according to the present disclosure is depicted as overwriting the noise level according to the comparative configuration.

As illustrated in FIG. 8A, employing the configuration of the switching power supply 10 makes it possible to reduce the level of conducted noise in each frequency band. As illustrated in FIG. 8B, employing the configuration of the switching power supply 10 makes it possible to reduce the level of radiated noise in each frequency band, for example, reduce the level of radiated noise in the 10-MHz band, which is greater than 10 [dBμV/m] according to the comparative configuration, to be less than 10 [dBμV/m].

In particular, the inductor 20 includes a stack structure of the first winding 21 and the second winding 22. The first winding 21 and the second winding 22 are in proximity to each other in the direction of thickness of the magnetic core 200. This facilitates increasing the capacitance of the parasitic capacitor 29 in the inductor 20. Therefore, due to the configuration of the inductor 20 mentioned above, in the switching power supply 10, a noise-balancing circuit formed by the above-mentioned closed electric circuit for confining switching noise can be implemented more reliably.

The inductor 20 is mounted to the surface 61 of the circuit board 60 in such a way that the bottom face FB200 is located closer to the surface 61 of the circuit board 60 than is the top face FU200, and that the bottom face FB200 faces the surface 61.

Due to the above-mentioned configuration, the first winding 21 is disposed closer to the circuit board 60 than is the second winding 22. In other words, in a direction orthogonal to the surface 61 of the circuit board 60, the second winding 22 is disposed outward of the first winding 21. In still other words, the first winding 21 is disposed between the second winding 22, and the surface 61 of the circuit board 60.

The one end of the wiring pattern 41 corresponds to the node ND0 between the switching element Q1 and the switching element Q2. Accordingly, noise due to the switching operation of the switching elements Q1 and Q2 flows to the wiring pattern 41. That is, the wiring pattern 41 can be said to be a switching node pattern.

The other end of the wiring pattern 41 is connected to the first winding 21. Switching noise thus flows into the first winding 21.

In contrast, one end of the second winding 22 is not directly connected to the node ND0 between the switching element Q1 and the switching element Q2, but connected to the node ND0 via the first winding 21. Further, the other end of the second winding 22 is connected to the wiring pattern 42. The wiring pattern 42 is connected to the output capacitor 32, and stable in potential. That is, the wiring pattern 42 can be said to be a stable-potential pattern.

As previously mentioned, with reference to the surface 61 of the circuit board 60, the second winding 22, which is connected to the stable-potential pattern, is disposed outward of the first winding 21, which is connected to the switching node pattern. As a result, even when switching noise is radiated from the first winding 21, the presence of the second winding 22 reduces radiation of the switching noise to the external environment of the switching power supply 10.

Further, the switching power supply 10 preferably includes the configuration described below.

Although not illustrated, in the switching power supply 10, the wiring pattern 41 has an area smaller than the area of the wiring pattern 42. That is, the switching node pattern has an area smaller than the area of the stable-potential pattern. This reduces radiation of switching noise from the wiring pattern 41, which is a source of radiation of the switching noise, to the external environment of the switching power supply 10 and to the chassis CHS.

Further, for the wiring pattern 41, the reduction in area is accomplished by reducing its length, without reducing its width as much as possible. As a result, the resistive component of the wiring pattern 41 decreases. This allows the switching power supply 10 to reduce losses due to current, and achieve high-efficiency power conversion. In particular, more efficient power conversion can be achieved for cases where the switching power supply 10 requires high current.

The wiring pattern 41 has an area smaller than the area of the inductor 20 as projected on the surface 61 of the circuit board 60 (the projected area of the inductor 20). This configuration of the switching power supply 10 makes it possible to reduce radiation or conduction of switching noise to the external environment and to the chassis CHS, and the resulting generation and conduction of common-mode noise.

In this regard, the area of the wiring pattern 42 is substantially equal to the projected area of the inductor 20, or greater than the area of the projected area of the inductor 20. This results in the presence of a large stable-potential surface relative to the overall area of the switching power supply 10 in plan view. This in turn makes it possible to reduce the influence of switching noise on the external environment of the switching power supply 10 and on the chassis CHS.

The switching power supply 10 constitutes a step-down DC-DC converter. The voltage applied to the inductor 20 (rectified and smoothed voltage) is lower than the voltage of the direct-current power source 81. For such a case, the above-mentioned configuration proves more effective. If, instead of the direct-current power source 81, a commercial alternating-current power source is used, and an alternating current is converted into a direct current for supply as an input via, for example, an inverter circuit, the voltage associated with the inductor 20 (rectified and smoothed voltage) is lower than the commercial alternating-current voltage. For this case as well, the above-mentioned configuration proves more effective.

### Second Embodiment

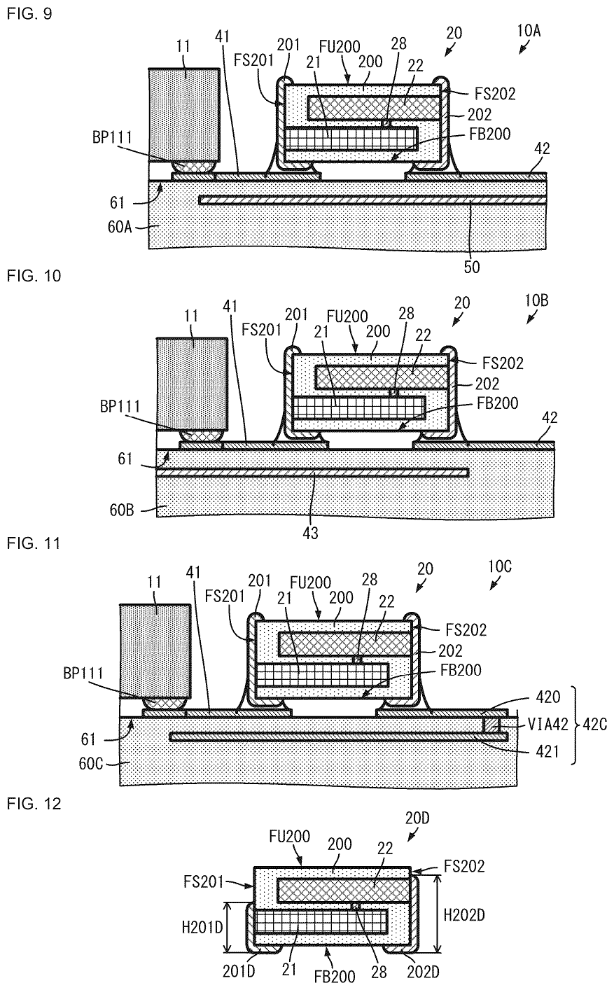

A switching power supply according to a second embodiment of the present disclosure will now be described with reference to the drawings. FIG. 9 is a side cross-sectional view of the switching power supply according to the second embodiment of the present disclosure, illustrating its configuration including a mounting portion where the inductor is mounted.

A switching power supply 10A according to the second embodiment differs from the switching power supply 10 according to the first embodiment with respect to a wiring pattern corresponding to the reference-potential-side wiring pattern 50. Other features of the switching power supply 10A are similar to those of the switching power supply 10, and such similar features will not be described in further detail.

The switching power supply 10A is implemented on a circuit board 60A. The circuit board 60A includes the reference-potential-side wiring pattern 50, which is a conductor pattern.

The reference-potential-side wiring pattern 50 is provided inside the circuit board 60A. The reference-potential-side wiring pattern 50 overlaps the inductor 20 (a region where the inductor 20 is mounted) and the wiring pattern 41 in plan view (when viewed in a direction orthogonal to the surface 61).

Due to the configuration mentioned above, a parasitic capacitor is formed between each of the inductor 20 and the wiring pattern 41, and the reference-potential-side wiring pattern 50. The main current for power conversion does not flow through the parasitic capacitor. Rather, the parasitic capacitor is of such a capacitance that allows passage therethrough of switching noise, which has a higher frequency than the main current.

Due to the above-mentioned configuration of the switching power supply 10A, the internal parasitic capacitance constituting the closed electric circuit can be made greater than the external parasitic capacitance formed with respect to the chassis CHS. As a result, switching noise is more effectively confined within the noise-balancing circuit, and the generation of common-mode noise is more effectively reduced.

Therefore, the switching power supply 10A makes it possible to more effectively reduce radiation or conduction of switching noise to the external environment, and generation and conduction of common-mode noise.

The reference-potential-side wiring pattern 50 may simply overlap part of at least one of the inductor 20 and the wiring pattern 41. Preferably, however, the reference-potential-side wiring pattern 50 overlaps both the inductor 20 and the wiring pattern 41.

### Third Embodiment

A switching power supply according to a third embodiment of the present disclosure will now be described with reference to the drawings. FIG. 10 is a side cross-sectional view of the switching power supply according to the third embodiment of the present disclosure, illustrating its configuration including a mounting portion where the inductor is mounted.

A switching power supply 10B according to the third embodiment differs from the switching power supply 10 according to the first embodiment with respect to a wiring pattern corresponding to an input-side high-potential pattern 43. The input-side high-potential pattern 43 corresponds to an “input wiring pattern.” Other features of the switching power supply 10B are similar to those of the switching power supply 10, and such similar features will not be described in further detail.

The input-side high-potential pattern 43 is a wiring pattern that connects the node ND1H at the high potential side of the input capacitor 31, and the switching IC 11 to each other.

The switching power supply 10B is implemented on a circuit board 60B. The circuit board 60B includes the input-side high-potential pattern 43, which is a conductor pattern.

The input-side high-potential pattern 43 is provided inside the circuit board 60B. The input-side high-potential pattern 43 overlaps the inductor 20 and the wiring pattern 41 in plan view.

Due to the configuration mentioned above, a parasitic capacitor is formed between each of the inductor 20 and the wiring pattern 41, and the input-side high-potential pattern 43. The main current for power conversion does not flow through the parasitic capacitor. Rather, the parasitic capacitor is of such a capacitance that allows passage therethrough of switching noise, which has a higher frequency than the main current.

Due to the above-mentioned configuration of the switching power supply 10B, the internal parasitic capacitance constituting the closed electric circuit can be made greater than the external parasitic capacitance formed with respect to the chassis CHS. As a result, switching noise is more effectively confined within the noise-balancing circuit, and the generation of common-mode noise is more effectively reduced.

Therefore, the switching power supply 10B makes it possible to more effectively reduce radiation or conduction of switching noise to the external environment, and generation and conduction of common-mode noise.

The input-side high-potential pattern 43 may simply overlap part of at least one of the inductor 20 and the wiring pattern 41. Preferably, however, the input-side high-potential pattern 43 overlaps both the inductor 20 and the wiring pattern 41.

### Fourth Embodiment

A switching power supply according to a fourth embodiment of the present disclosure will now be described with reference to the drawings. FIG. 11 is a side cross-sectional view of the switching power supply according to the fourth embodiment of the present disclosure, illustrating its configuration including a mounting portion where the inductor is mounted.

A switching power supply 10C according to the fourth embodiment differs from the switching power supply 10 according to the first embodiment with respect to a wiring pattern 42C. Other features of the switching power supply 10C are similar to those of the switching power supply 10, and such similar features will not be described in further detail.

The switching power supply 10C is implemented on a circuit board 60C. The circuit board 60C includes the wiring pattern 42C, which is a conductor pattern.

The wiring pattern 42C includes a wiring pattern 420, a wiring pattern 421, and a connection conductor VIA42. The wiring pattern 420 is provided on the surface 61 of the circuit board 60C. The wiring pattern 420 includes a land for the inductor 20. The wiring pattern 421 is provided inside the circuit board 60C. The wiring pattern 421 is connected to the wiring pattern 420 via the connection conductor VIA42. The wiring pattern 421 overlaps the inductor 20 and the wiring pattern 41 in plan view.

Due to the configuration mentioned above, a parasitic capacitor is formed between each of the inductor 20 and the wiring pattern 41, and the wiring pattern 421. The main current for power conversion does not flow through the parasitic capacitor. Rather, the parasitic capacitor is of such a capacitance that allows passage therethrough of switching noise, which has a higher frequency than the main current.

Due to the above-mentioned configuration of the switching power supply 10C, the internal parasitic capacitance constituting the closed electric circuit can be made greater than the external parasitic capacitance formed with respect to the chassis CHS. As a result, switching noise is more effectively confined within the noise-balancing circuit, and the generation of common-mode noise is more effectively reduced.

Therefore, the switching power supply 10C makes it possible to more effectively reduce radiation or conduction, to the external environment, of switching noise including common-mode noise, and generation and conduction of common-mode noise.

The wiring pattern 421 may simply overlap part of at least one of the inductor 20 and the wiring pattern 41. Preferably, however, the wiring pattern 421 overlaps both the inductor 20 and the wiring pattern 41.

### Fifth Embodiment

A switching power supply according to a fifth embodiment of the present disclosure will now be described with reference to the drawings. FIG. 12 is a see-through side view of an inductor according to the fifth embodiment of the present disclosure, illustrating the configuration of its winding conductors.

The switching power supply according to the fifth embodiment differs from the switching power supply 10 according to the first embodiment with respect to an inductor 20D. Other features of the switching power supply according to the fifth embodiment are similar to those of the switching power supply 10, and such similar features will not be described in further detail.

As illustrated in FIG. 12, the inductor 20D includes a first terminal 201D, and a second terminal 202D. The first terminal 201D is provided so as to extend over the side face FS201 and the bottom face FB200 of the magnetic core 200. The second terminal 202D is provided to extend over the side face FS202 and the bottom face FB200 of the magnetic core 200.

The first terminal 201D has a height H201D lower than a height H202D of the second terminal 202D. The first terminal 201D is provided over the entire width of the side face FS201. The second terminal 202D is provided over the entire width of the side face FS202. As a result, the area of a portion of the first terminal 201D provided on the side face FS201 is smaller than the area of a portion of the second terminal 202D provided on the side face FS202.

The above-mentioned configuration reduces radiation of switching noise from the first terminal 201D.

### Sixth Embodiment

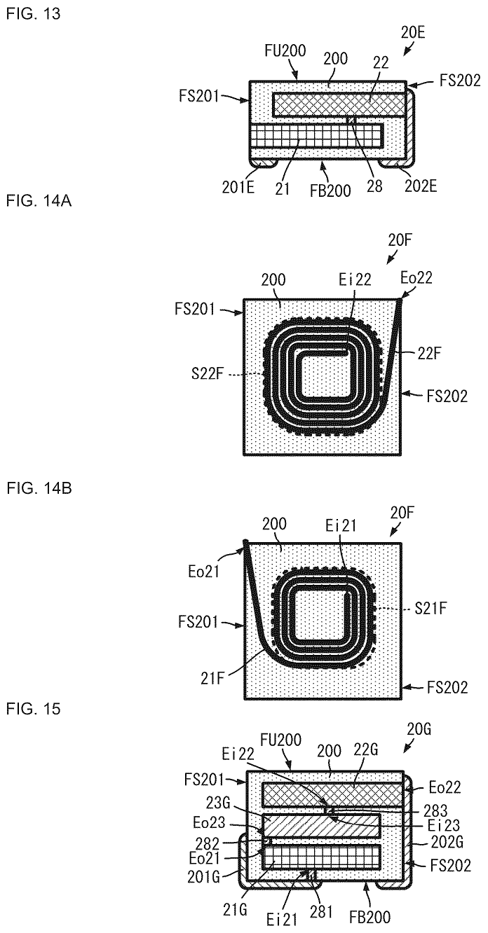

A switching power supply according to a sixth embodiment of the present disclosure will now be described with reference to the drawings. FIG. 13 is a see-through side view of an inductor according to the sixth embodiment of the present disclosure, illustrating the configuration of its winding conductors.

The switching power supply according to the sixth embodiment differs from the switching power supply 10 according to the first embodiment with respect to an inductor 20E. Other features of the switching power supply according to the sixth embodiment are similar to those of the switching power supply 10, and such similar features will not be described in further detail.

As illustrated in FIG. 13, the inductor 20E includes a first terminal 201E, and a second terminal 202E. The first terminal 201E is provided on the bottom face FB200 of the magnetic core 200, and not provided on the side face FS201. The second terminal 202E is provided to extend over the side face FS202 and the bottom face FB200 of the magnetic core 200.

The above-mentioned configuration reduces radiation of switching noise from the first terminal 201E.

### Seventh Embodiment

A switching power supply according to a seventh embodiment of the present disclosure will now be described with reference to the drawings. FIG. 14A and FIG. 14B are see-through plan views of an inductor according to the seventh embodiment of the present disclosure, each illustrating the corresponding one of its winding conductors.

The switching power supply according to the seventh embodiment differs from the switching power supply 10 according to the first embodiment with respect to an inductor 20F. Other features of the switching power supply according to the seventh embodiment are similar to those of the switching power supply 10, and such similar features will not be described in further detail.

As illustrated in FIG. 14A and FIG. 14B, the inductor 20F includes a first winding 21F, and a second winding 22F. The second winding 22F has a number of turns greater than the number of turns of the first winding 21F, and in plan view, the outer shape of the second winding 22F has an area S22F greater than an area S21F of the outer shape of the first winding 21F.

Further, in plan view, the coiled shape portion of the second winding 22F overlaps the coiled shape portion of the first winding 21F.

The above-mentioned configuration allows the second winding 22F to more effectively reduce radiation of the switching noise from the first winding 21F to the chassis CHS and to the external environment.

### Eighth Embodiment

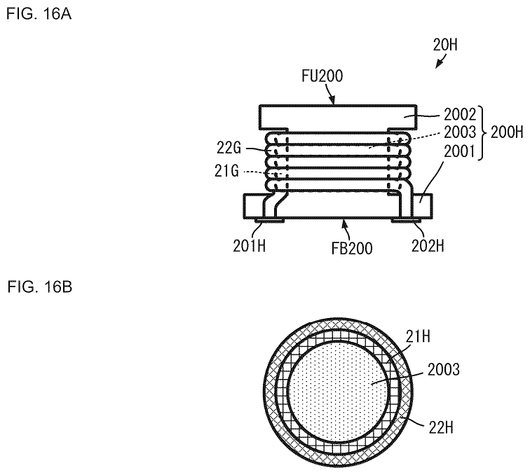

A switching power supply according to an eighth embodiment of the present disclosure will now be described with reference to the drawings. FIG. 15 is a see-through side view of an inductor according to the eighth embodiment of the present disclosure, illustrating the configuration of its winding conductors.

The switching power supply according to the eighth embodiment differs from the switching power supply 10 according to the first embodiment with respect to an inductor 20G. Other features of the switching power supply according to the eighth embodiment are similar to those of the switching power supply 10, and such similar features will not be described in further detail.

As illustrated in FIG. 15, the inductor 20G includes a first winding 21G, a second winding 22G, and a third winding 23G. As with the first winding 21 and the second winding 22 mentioned above, the first winding 21G, the second winding 22G, and the third winding 23G are winding conductors.

The first winding 21G, the second winding 22G, and the third winding 23G are disposed in the following order from the bottom face FB200 of the magnetic core 200 toward the top face FU200: the first winding 21G, the third winding 23G, and the second winding 22G.

The inner end portion Ei21 of the first winding 21G is connected via a connection conductor 281 to a portion (bottom face portion) of a first terminal 201G that is located on the bottom face of the magnetic core 200. More specifically, with the first winding 21G seen in plan view, the inner end of the first winding 21G is connected to a position near the center of the bottom face portion of the first terminal 201G. The first terminal 201G may be provided only on the bottom face of the magnetic core 200. The outer end portion Eo21 of the first winding 21G is connected via a connection conductor 282 to an outer end portion Eo23 of the third winding 23G. An inner end portion Ei23 of the third winding 23G is connected via a connection conductor 283 to the inner end portion Ei22 of the second winding 22G. The outer end portion Eo22 of the second winding 22G is connected to a second terminal 202G.

As described above, the inductor used in the switching power supply may include three or more winding conductor layers.

In this case, as in the inductor 20G, the first winding 21G, which is closest in the electric circuit to the switching node pattern and the first terminal 201G, is connected at the inner end portion Ei21 to the first terminal 201G and the switching node pattern. The noise level is thus high in the central portion of the inductor 20G in plan view. As a result, radiation of noise from the inductor 20G to the chassis CHS and to the external environment is more effectively reduced.

### Ninth Embodiment

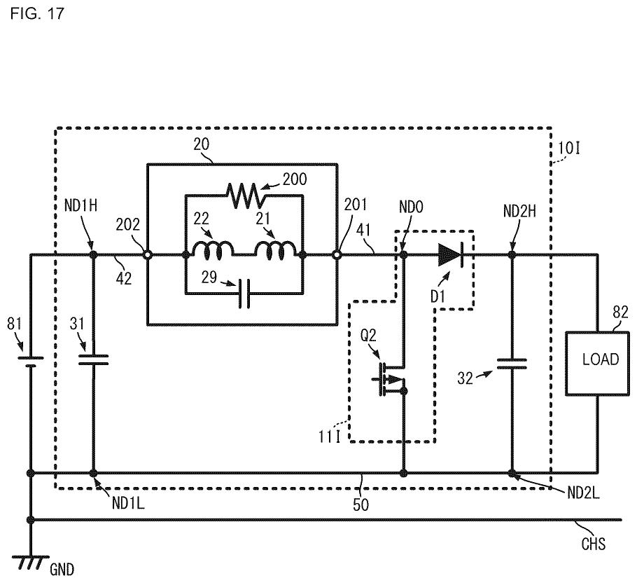

A switching power supply according to a ninth embodiment of the present disclosure will now be described with reference to the drawings. FIG. 16A is a side view of an inductor according to the ninth embodiment of the present disclosure illustrating its configuration, and FIG. 16B conceptually illustrates the inductor with conductor patterns wound around a magnetic core.

The switching power supply according to the ninth embodiment differs from the switching power supply 10 according to the first embodiment with respect to an inductor 20H. Other features of the switching power supply according to the ninth embodiment are similar to those of the switching power supply 10, and such similar features will not be described in further detail.

The inductor 20H includes a magnetic core 200H, a fourth winding 21H, a fifth winding 22H, a first terminal 201H, and a second terminal 202H.

The magnetic core 200H includes a bottom plate 2001, a top plate 2002, and a support column 2003. The support column 2003 is disposed between the bottom plate 2001 and the top plate 2002, and connected to the bottom plate 2001 and the top plate 2002.

The fourth winding 21H is a winding conductor wound around the support column 2003. One end of the fourth winding 21H is connected to the first terminal 201H provided on the bottom plate 2001.

The fifth winding 22H is a winding conductor wound around the support column 2003 with the fourth winding 21H interposed therebetween. That is, with reference to the support column 2003, the fifth winding 22H is disposed outside the fourth winding 21H. One end of the fifth winding 22H is connected to the other end of the fourth winding 21H. The other end of the fifth winding 22H is connected to the second terminal 202H provided on the bottom plate 2001.

The first terminal 201H is connected to the wiring pattern 41, which is the switching node pattern. The second terminal 202H is connected to the wiring pattern 42, which is the stable-potential pattern.

Employing the inductor 20H configured as described above also makes it possible to obtain an operational effect similar to that of the switching power supply 10 employing the inductor 20 described above.

### Tenth Embodiment

A switching power supply according to a tenth embodiment of the present disclosure will now be described with reference to the drawings. FIG. 17 is a circuit diagram illustrating a schematic configuration of the switching power supply according to the tenth embodiment of the present disclosure.

Although the switching power supply 10 according to the first embodiment is a step-down DC-DC converter, a switching power supply 10I according to the tenth embodiment is a step-up DC-DC converter. In the switching power supply 10I, the configuration of the inductor 20, and the respective shapes of the wiring pattern 41 and the wiring pattern 42 are similar to those in the switching power supply 10.

As illustrated in FIG. 17, the switching power supply 10I includes a switching IC 11I, the inductor 20, the input capacitor 31, and the output capacitor 32. The switching IC 11I includes a switching control circuit (not illustrated), a switching element D1, and the switching element Q2. The switching element DI corresponds to the “first switching element”, and the switching element Q2 corresponds to the “second switching element.” The switching element D1 and the switching element Q2 are power semiconductor elements.

The switching power supply 10I is electrically connected to the direct-current power source 81. More specifically, the input capacitor 31 is electrically connected in parallel with the direct-current power source 81. The connection point between the positive electrode of the direct-current power source 81 and the input capacitor 31 is the node ND1H, and the connection point between the negative electrode of the direct-current power source 81 and the input capacitor 31 is the node ND1L.

The switching element D1 and the switching element Q2 are electrically connected in series with each other. More specifically, the anode of the switching element D1, and the drain of the switching element Q2 are electrically connected to each other. The connection point between the switching element D1 and the switching element Q2 is the node ND0.

The wiring pattern 42 is connected to the node ND1L. The second terminal 202 of the inductor 20 is connected to the wiring pattern 42. The wiring pattern 41 is connected to the first terminal 201 of the inductor 20. The wiring pattern 41 is connected to the node ND0.

The one terminal (high-side terminal) of the output capacitor 32 is connected to the cathode of the switching element D1. The connection point between the cathode of the switching element D1, and the one terminal of the output capacitor 32 is the node ND2H.

The other terminal (low-side terminal) of the output capacitor 32 is connected to the reference-potential-side wiring pattern 50. The connection point between the other terminal of the output capacitor 32 and the reference-potential-side wiring pattern 50 is the node ND2L.

The reference-potential-side wiring pattern 50 is connected to the node ND1L (the connection point between the negative electrode of the direct-current power source 81 and the input capacitor 31).

The configuration mentioned above makes it possible to implement, in the switching power supply 10I, a noise-balancing circuit including the following components: the wiring pattern 41, the inductor 20, the wiring pattern 42, the input capacitor 31, the reference-potential-side wiring pattern 50, and the output capacitor 32. As a result, as with the switching power supply 10, the switching power supply 10I makes it possible to reduce radiation of switching noise to the external environment, and generation and conduction of common-mode noise and its radiation to the external environment, and also reduce noise level by means of the noise-balancing circuit. Therefore, the switching power supply 10I makes it possible to more effectively reduce radiation or conduction of switching noise to the chassis CHS and its radiation to the external environment, and also generation and conduction of common-mode noise.

For each of the switching power supplies according to the above-mentioned embodiments, the common-mode noise reduction effect can be verified as follows, for example.

In a first example, a Delta-type LISN is connected to the wiring pattern at each of the positive and negative sides of the direct-current power source 81, and a spectrum analyzer is connected to the Delta-type LISN. By measuring the output voltage of the Delta-type LISN with the spectrum analyzer, the common-mode noise reduction effect can be verified.

In a second example, a current sensor is connected to the wiring pattern at each of the positive and negative sides of the direct-current power source 81, and a spectrum analyzer is connected to the current sensor. By measuring the output voltage of the current sensor with the spectrum analyzer, the common-mode noise reduction effect can be verified.

In a third example, a LISN is connected to the wiring pattern at the negative side of the direct-current power source 81, and the LISN is connected to the chassis CHS. A current sensor (current probe) is placed on the connection line between the LISN and the chassis CHS, and a spectrum analyzer is connected to the current sensor. By measuring the output voltage of the current sensor with the spectrum analyzer, the common-mode noise reduction effect can be verified.

The configurations according to the above-mentioned embodiments can be combined as appropriate to obtain operational effects corresponding to individual combinations.
<1>A switching power supply comprising an input capacitor; a first switching element and a second switching element that are electrically connected to the input capacitor; an inductor including a winding conductor, a magnetic core, a first terminal electrically connected to one end of the winding conductor, and a second terminal electrically connected to an other end of the winding conductor; an output capacitor; and a circuit board to which the input capacitor, the first switching element, the second switching element, the inductor, and the output capacitor are mounted. The circuit board includes a first wiring pattern that electrically connects a connection node between the first switching element and the second switching element, and the first terminal to each other, a second wiring pattern that electrically connects the second terminal and the output capacitor to each other, and a reference potential pattern. Also, in plan view of the circuit board, the first wiring pattern has an area smaller than an area of the second wiring pattern. The inductor has, between the first terminal and the second terminal, an internal parasitic capacitance of the inductor due to construction of the winding conductor and the magnetic core. In addition, due to positioning of the circuit board with respect to a chassis, at a switching frequency at which the first switching element and the second switching element are operated, the internal parasitic capacitance of the inductor is greater than an external parasitic capacitance between the magnetic core and the chassis. Furthermore, the internal parasitic capacitance of the inductor, the second wiring pattern, the output capacitor, the reference potential pattern of the circuit board, the input capacitor, and the first wiring pattern constitute a noise-balancing circuit formed by a closed electric circuit, the noise-balancing circuit being configured to cancel generation of electromagnetic noise caused by switching operation of the first switching element and the second switching element, and to reduce generation of common-mode noise radiated or conducted from the inductor.
<2>The switching power supply according to <1>, wherein the winding conductor includes a first winding and a second winding disposed in spaced relation to each other in a direction of thickness of the magnetic core. Also, the internal parasitic capacitance is formed by the first winding and the second winding.
<3>The switching power supply according to <1>or <2>, wherein the second winding is positioned farther from the circuit board than is the first winding, and in plan view of the inductor, the second winding has an outer shape smaller than an outer shape of the first winding, and the second winding overlaps the first winding.
<4>The switching power supply according to any one of <1>to <3>, wherein the inductor includes at least one third winding electrically connected between the first winding and the first winding. Also, the first winding has an inner end electrically connected to the first terminal, and the second winding has an outer end electrically connected to the second terminal.
<5>The switching power supply according to any one of <1>to <4>, wherein in plan view of the circuit board, the reference potential pattern is provided in a region that does not overlap a region where the inductor is mounted.

<6>The switching power supply according to any one of <1>to <5>, wherein the circuit board includes an input wiring pattern electrically connected to the input capacitor, and in plan view of the circuit board, the input wiring pattern is provided in a region that overlaps a region where the inductor is mounted.

<7>The switching power supply according to any one of <1>to <6>, wherein in plan view of the circuit board, a portion of the second wiring pattern is provided in a region that overlaps a region where the inductor is mounted.

<8>The switching power supply according to any one of <1>to <7>, wherein the magnetic core has a bottom face, a first side face, and a second side face, the first terminal is provided to extend over the bottom face and the first side face, the second terminal is provided to extend over the bottom face and the second side face, and an area of a portion of the first terminal provided on the first side face is smaller than an area of a portion of the second terminal provided on the second side face.

<9>The switching power supply according to any one of <1>to <8>, wherein the magnetic core has a bottom face, a first side face, and a second side face, the first terminal is provided only on the bottom face, and the second terminal is provided to extend over the bottom face and the second side face.

<10>The switching power supply according to any one of <1>to <9>, wherein in plan view of the inductor, the first wiring pattern has an area smaller than an area of the inductor.

<11>The switching power supply according to any one of <1>to <10>, wherein the first switching element, the second switching element, and the inductor constitute a non-isolated power conversion circuit, and a rectified and smoothed voltage applied to the inductor is less than a rectified and smoothed commercial alternating-current voltage.
<12>A switching power supply comprising an input capacitor; an inductor including a winding conductor, a magnetic core, a first terminal electrically connected to one end of the winding conductor, and a second terminal electrically connected to an other end of the winding conductor; a first switching element and a second switching element that are electrically connected to the inductor; an output capacitor; and a circuit board to which the input capacitor, the first switching element, the second switching element, the inductor, and the output capacitor are mounted. The circuit board includes a first wiring pattern that electrically connects a connection node between the first switching element and the second switching element, and the first terminal to each other, a second wiring pattern that electrically connects the second terminal and the input capacitor to each other, and a reference potential pattern. The first wiring pattern has an area smaller than an area of the second wiring pattern. The inductor has, between the first terminal and the second terminal, an internal parasitic capacitance of the inductor due to construction of the winding conductor and the magnetic core. Also, due to positioning of the circuit board with respect to a chassis, at a switching frequency of the first switching element and the second switching element, the internal parasitic capacitance of the inductor is greater than an external parasitic capacitance between the magnetic core and the chassis. In addition, the internal parasitic capacitance of the inductor, the second wiring pattern, the output capacitor, the reference potential pattern of the circuit board, the input capacitor, and the first wiring pattern constitute a noise-balancing circuit formed by a closed electric circuit, the noise-balancing circuit being configured to cancel generation of electromagnetic noise caused by switching operation of the first switching element and the second switching element, and to reduce generation of common-mode noise radiated or conducted from the inductor.

What is claimed is:

1. A switching power supply comprising:
an input capacitor;
a first switching element and a second switching element that are electrically connected to the input capacitor;
an inductor including
a winding conductor,
a magnetic core,
a first terminal electrically connected to one end of the winding conductor, and
a second terminal electrically connected to an other end of the winding conductor;
an output capacitor; and
a circuit board to which the input capacitor, the first switching element, the second switching element, the inductor, and the output capacitor are mounted,
the circuit board includes
a first wiring pattern that electrically connects a connection node between the first switching element and the second switching element, and the first terminal to each other,
a second wiring pattern that electrically connects the second terminal and the output capacitor to each other, and
a reference potential pattern,
in plan view of the circuit board, the first wiring pattern has an area smaller than an area of the second wiring pattern,
the inductor has, between the first terminal and the second terminal, an internal parasitic capacitance of the inductor due to construction of the winding conductor and the magnetic core,
due to positioning of the circuit board with respect to a chassis, at a switching frequency at which the first switching element and the second switching element are operated, the internal parasitic capacitance of the inductor is greater than an external parasitic capacitance between the magnetic core and the chassis, and
the internal parasitic capacitance of the inductor, the second wiring pattern, the output capacitor, the reference potential pattern of the circuit board, the input capacitor, and the first wiring pattern configure a noise-balancing circuit including a closed electric circuit, the noise-balancing circuit being configured to cancel generation of electromagnetic noise caused by switching operation of the first switching element and the second switching element, and to reduce generation of common-mode noise radiated or conducted from the inductor.

2. The switching power supply according to claim 1, wherein
the winding conductor includes a first winding and a second winding in spaced relation to each other in a direction of thickness of the magnetic core, and
the internal parasitic capacitance is configured by the first winding and the second winding.

3. The switching power supply according to claim 1, wherein
the winding conductor includes a first winding and a second winding,
the second winding is positioned farther from the circuit board than is the first winding, and
in plan view of the inductor, the second winding has an outer shape smaller than an outer shape of the first winding, and the second winding overlaps the first winding.

4. The switching power supply according to claim 1, wherein
the winding conductor includes a first winding and a second winding
the inductor includes at least one third winding electrically connected between the first winding and the second winding,
the first winding has an inner end electrically connected to the first terminal, and
the second winding has an outer end electrically connected to the second terminal.

5. The switching power supply according to claim 1, wherein
in plan view of the circuit board, the reference potential pattern is in a region that does not overlap a region where the inductor is mounted.

6. The switching power supply according to claim 1, wherein
the circuit board includes an input wiring pattern electrically connected to the input capacitor, and
in plan view of the circuit board, the input wiring pattern is in a region that overlaps a region where the inductor is mounted.

7. The switching power supply according to claim 1, wherein
in plan view of the circuit board, a portion of the second wiring pattern is in a region that overlaps a region where the inductor is mounted.

8. The switching power supply according to claim 1, wherein
the magnetic core has a bottom face, a first side face, and a second side face,
the first terminal extends over the bottom face and the first side face,
the second terminal extends over the bottom face and the second side face, and
an area of a portion of the first terminal on the first side face is smaller than an area of a portion of the second terminal on the second side face.

9. The switching power supply according to claim 1, wherein
the magnetic core has a bottom face, a first side face, and a second side face,
the first terminal is only on the bottom face, and
the second terminal extends over the bottom face and the second side face.

10. The switching power supply according to claim 1, wherein
in plan view of the inductor, the first wiring pattern has an area smaller than an area of the inductor.

11. The switching power supply according to claim 1, wherein
the first switching element, the second switching element, and the inductor configure a non-isolated power conversion circuit, and
a voltage applied to the inductor is less than a rectified and smoothed commercial alternating-current voltage.

12. The switching power supply according to claim 2, wherein
the second winding is positioned farther from the circuit board than is the first winding, and
in plan view of the inductor, the second winding has an outer shape smaller than an outer shape of the first winding, and the second winding overlaps the first winding.

13. The switching power supply according to claim 2, wherein
the inductor includes at least one third winding electrically connected between the first winding and the second winding,
the first winding has an inner end electrically connected to the first terminal, and
the second winding has an outer end electrically connected to the second terminal.

14. The switching power supply according to claim 2, wherein
in plan view of the circuit board, the reference potential pattern is in a region that does not overlap a region where the inductor is mounted.

15. The switching power supply according to claim 2, wherein
the circuit board includes an input wiring pattern electrically connected to the input capacitor, and
in plan view of the circuit board, the input wiring pattern is in a region that overlaps a region where the inductor is mounted.

16. The switching power supply according to claim 2, wherein
in plan view of the circuit board, a portion of the second wiring pattern is in a region that overlaps a region where the inductor is mounted.

17. The switching power supply according to claim 2, wherein
the magnetic core has a bottom face, a first side face, and a second side face,
the first terminal extends over the bottom face and the first side face,
the second terminal extends over the bottom face and the second side face, and
an area of a portion of the first terminal on the first side face is smaller than an area of a portion of the second terminal on the second side face.

18. The switching power supply according to claim 2, wherein
the magnetic core has a bottom face, a first side face, and a second side face,
the first terminal is only on the bottom face, and
the second terminal extends over the bottom face and the second side face.

19. The switching power supply according to claim 2, wherein
in plan view of the inductor, the first wiring pattern has an area smaller than an area of the inductor.

20. A switching power supply comprising:
an input capacitor;
an inductor including
a winding conductor,
a magnetic core,
a first terminal electrically connected to one end of the winding conductor, and
a second terminal electrically connected to an other end of the winding conductor;
a first switching element and a second switching element that are electrically connected to the inductor;
an output capacitor; and
a circuit board to which the input capacitor, the first switching element, the second switching element, the inductor, and the output capacitor are mounted,
wherein the circuit board includes
a first wiring pattern that electrically connects a connection node between the first switching element and the second switching element, and the first terminal to each other,
a second wiring pattern that electrically connects the second terminal and the input capacitor to each other, and
a reference potential pattern,
wherein the first wiring pattern has an area smaller than an area of the second wiring pattern,
wherein the inductor has, between the first terminal and the second terminal, an internal parasitic capacitance of the inductor due to construction of the winding conductor and the magnetic core,
wherein due to positioning of the circuit board with respect to a chassis, at a switching frequency of the first switching element and the second switching element, the internal parasitic capacitance of the inductor is greater than an external parasitic capacitance between the magnetic core and the chassis, and
wherein the internal parasitic capacitance of the inductor, the second wiring pattern, the output capacitor, the reference potential pattern of the circuit board, the input capacitor, and the first wiring pattern configure a noise-balancing circuit including a closed electric circuit, the noise-balancing circuit being configured to cancel generation of electromagnetic noise caused by switching operation of the first switching element and the second switching element, and to reduce generation of common-mode noise radiated or conducted from the inductor.
